(19) United States
(12) Patent Application Publication
(10) Pub. No.: US 2026/0012153 A1
(43) Pub. Date: Jan. 8, 2026

(54) ELECTRONIC DEVICE

(71) Applicant: SOSHIN ELECTRIC CO., LTD., Saku-City (JP)

(72) Inventors: Hiroyuki ISONO, Saku-City (JP); Ken EJIMA, Saku-City (JP); Yoshiharu IMAI, Saku-City (JP)

(73) Assignee: SOSHIN ELECTRIC CO., LTD., Saku-City (JP)

(21) Appl. No.: 19/101,300

(22) PCT Filed: Aug. 7, 2023
(86) PCT No.: PCT/JP2023/028676

§ 371 Date: Feb. 5, 2025

(30) Foreign Application Priority Data
Aug. 10, 2022 (JP) 2022-127904

(51) Int. Cl. H03H 7/01; H03H 1/00

(52) U.S. Cl. CPC H03H 7/0115; H03H 1/00; H03H 2001/0078; H03H 2001/0085

(57) ABSTRACT

An electronic device comprises: a common terminal provided on a dielectric substrate; an inductor formed in the dielectric substrate; a first filter formed in the dielectric substrate; and a second filter formed in the dielectric substrate. The frequency of the pass-band of the second filter is higher than the frequency of the pass-band of the first filter. The first filter is electrically connected to the common terminal via the inductor. The second filter is electrically connected to the common terminal via a first partial inductor which is a part of the inductor.

### TECHNICAL FIELD

The present invention relates to an electronic device.

### BACKGROUND ART

An electronic device capable of separating an input signal into a plurality of signals having different frequency bands has attracted attention. Such an electronic device is referred to as a demultiplexer. An electronic device capable of separating an input signal into three frequency bands is called a triplexer (JP 2013-243600 A).

### SUMMARY OF THE INVENTION

There is a long awaited need for more satisfactory electronic devices.

The present invention has the object of meeting the aforementioned need.

An electronic device according to one aspect of the present invention includes a dielectric substrate, a common terminal provided on the dielectric substrate and configured to input or output a signal, an inductor formed in the dielectric substrate, a first filter formed in the dielectric substrate, and a second filter formed in the dielectric substrate, wherein a frequency of a passband of the second filter is higher than a frequency of a passband of the first filter, the first filter is electrically coupled to the common terminal through the inductor, the inductor includes a first partial inductor and a second partial inductor connected in series to the first partial inductor, and the second filter is electrically coupled to the common terminal through the first partial inductor, but not through the second partial inductor.

According to the present invention, it is possible to provide a more satisfactory electronic device.

### BRIEF DESCRIPTION OF DRAWINGS

FIG. 1 is a circuit diagram illustrating an electronic device according to an embodiment;

FIG. 2 is a perspective view illustrating the electronic device according to the embodiment;

FIG. 3 is a perspective view illustrating a portion of the electronic device according to the embodiment;

FIG. 4 is a side view illustrating a portion of the electronic device according to the embodiment;

FIG. 5 is a perspective view illustrating the electronic device according to the embodiment;

FIG. 6 is a graph illustrating an evaluation result of the electronic device according the embodiment; and

FIG. 7 is a circuit diagram illustrating an electronic device according to a reference example.

### DETAILED DESCRIPTION OF THE INVENTION

### Embodiment

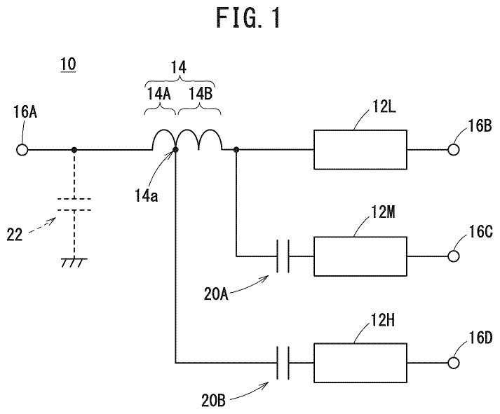

An electronic device according to an embodiment will be described with reference to the drawings. FIG. 1 is a circuit diagram illustrating an electronic device according to the present embodiment.

As shown in FIG. 1, an electronic device 10 according to the present embodiment includes a plurality of filters 12L, 12M, and 12H. In this instance, the electronic device 10 is a demultiplexer, but the present invention is not limited to this.

The frequencies (passband frequencies) of the passband (passing frequency band) of the filter 12L are relatively low. The frequencies of the passband of the filter 12H are relatively high. The frequencies of the passband of the filter 12M are higher than the frequencies of the passband of the filter 12L and lower than the frequencies of the passband of the filter 12H.

The electronic device 10 further includes an inductor 14. The inductor 14 includes a partial inductor (first partial inductor) 14A and a partial inductor (second partial inductor) 14B. The partial inductor 14B is connected in series with the partial inductor 14A.

One end (input node, input end) of the filter (low band filter) 12L is electrically coupled to a common terminal (common input terminal) 16A through the inductor 14. Another end (output node, output end) of the filter 12L is electrically connected to the terminal (output terminal) 16B.

One end (input node, input end) of the filter (middle band filter) 12M is electrically coupled to the common terminal 16A through the inductor 14. More specifically, the one end of the filter 12M is electrically coupled to the common terminal 16A via a capacitor 20A and the inductor 14. Another end (output node) of the filter 12M is electrically connected to a terminal (output terminal) 16C.

One end (input node) of the filter (high band filter) 12H is electrically coupled to the common terminal 16A through the partial inductor 14A. More specifically, the one end of the filter 12H is electrically coupled to the common terminal 16A through a capacitor 20B and the partial inductor 14A, but not through the partial inductor 14B. The one end of the filter 12H is electrically coupled to a portion where the partial inductor 14A and the partial inductor 14B are connected to each other, through the capacitor 20B. That is, the one end of the filter 12H is electrically coupled to a connection node 14a through the capacitor 20B. Another end (output node) of the filter 12H is electrically connected to the terminal (output terminal) 16D.

One end of the partial inductor 14A is connected to the common terminal 16A. Another end of the partial inductor 14A is connected to one end of the partial inductor 14B at the connection node 14a. Another end of the partial inductor 14B is connected to the one end of the filter 12L and one end of the capacitor 20A. Another end of the capacitor 20A is connected to the one end of the filter 12M. One end of the capacitor 20B is connected to the partial inductor 14A at the connection node 14a. Another end of the capacitor 20B is connected to the one end of the filter 12H.

In this instance, the case where the filter 12M is electrically coupled to the common terminal 16A through the inductor 14 will be described as an example, but the present invention is not to this feature. The filter 12M may be electrically coupled to the common terminal 16A through the partial inductor 14A, but not through the partial inductor 14B. That is, the filter 12M may be electrically coupled to the common terminal 16A through a portion of the inductor 14.

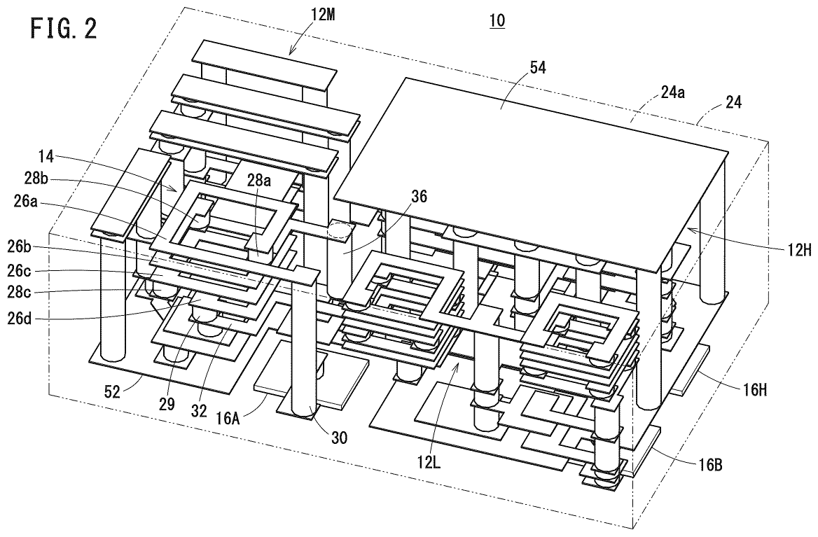

FIG. 2 is a perspective view showing the electronic device according to the present embodiment.

As shown in FIG. 2, the electronic device 10 according to the present embodiment is equipped with a dielectric substrate 24. The dielectric substrate 24 is formed, for example, in the shape of a rectangular parallelepiped, although the present embodiment is not necessarily limited to this feature. The dielectric substrate 24 is constituted by laminating (stacking in layers) a plurality of ceramic sheets (dielectric ceramic sheets).

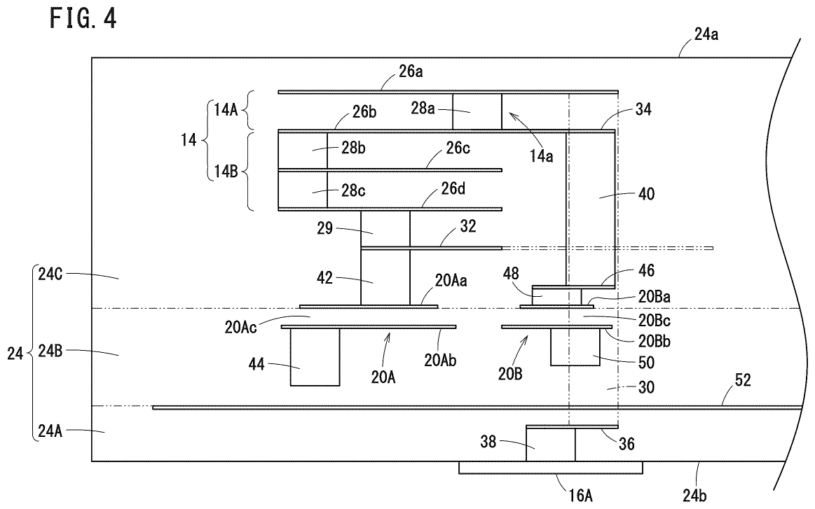

The dielectric substrate 24 has a main surface (first main surface, upper surface) 24a and a main surface (second main surface, lower surface) 24b (see FIG. 4). The main surface 24a and the main surface 24b are positioned on opposite sides of each other.

The filters 12L, 12M, and 12H are formed in the dielectric substrate 24. The inductor (inductor coil) 14 is further formed in the dielectric substrate 24.

A shielding layer 54 is formed on the main surface 24a of the dielectric substrate 24. The shielding layer 54 may be formed in the dielectric substrate 24.

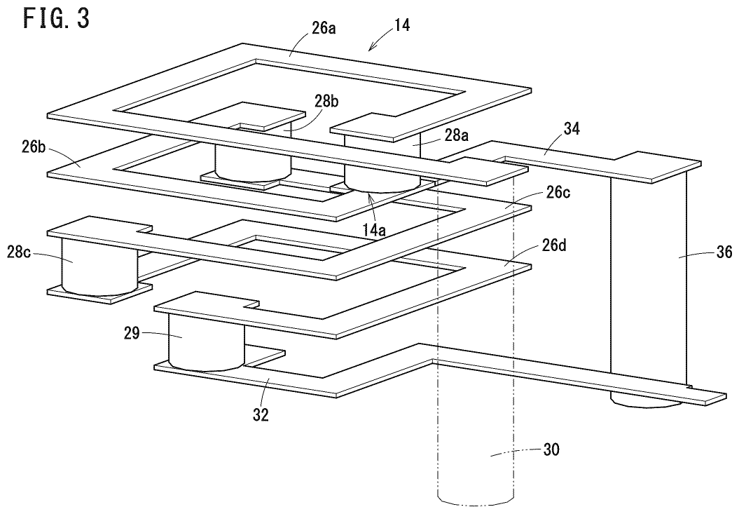

FIG. 3 is a perspective view illustrating a portion of the electronic device according to the present embodiment. In FIG. 3, the inductor 14 is shown. FIG. 4 is a side view illustrating a portion of the electronic device according to the embodiment. FIG. 4 shows the inductor 14 and the capacitors 20A and 20B. In FIGS. 3 and 4, only some components are shown for simplification of description.

As shown in FIG. 3, the inductor 14 is configured by combining a plurality of winding patterns 26a to 26d and a plurality of via electrodes 28a to 28c. When the individual winding patterns are described without distinguishing therebetween, the reference numeral 26 will be used, and when the winding patterns are described while distinguishing therebetween, the reference numerals 26a to 26d will be used. When the individual via electrodes are described without distinguishing therebetween, the reference numeral 28 will be used, and when the via electrodes are described while distinguishing therebetween, the reference numerals 28a to 28c will be used. The inductor 14 is also referred to as a spiral inductor. The inductor 14 is formed three dimensionally.

As shown in FIG. 3, one end of the winding pattern 26a is connected to the upper end of a via electrode 30. The lower end of the via electrode 30 is electrically connected to the common terminal 16A through a conductive pattern 36 (see FIG. 4) and a via electrode 38 (see FIG. 4). That is, the one end of the winding pattern 26a is electrically connected to the common terminal 16A through the via electrode 30. In other words, one end of the inductor 14 is electrically connected to the common terminal 16A through the via electrode 30. The via electrode 30 penetrates a dielectric layer 24B (see FIG. 4) described later. The other end of the winding pattern 26a is connected to an upper end of the via electrode 28a. The lower end of the via electrode 28a is connected to one end of the winding pattern 26b. The other end of the winding pattern 26b is connected to an upper end of the via electrode 28b. The lower end of the via electrode 28b is connected to one end of the winding pattern 26c. The other end of the winding pattern 26c is connected to the upper end of the via electrode 28c. The lower end of the via electrode 28c is connected to one end of the winding pattern 26d. The other end of the winding pattern 26d is connected to the upper end of a via electrode 29. The lower end of the via electrode 29 is electrically connected to the filter 12L (see FIG. 2) through a conductive pattern 32.

As shown in FIG. 4, the inductor 14 is connected to the capacitor 20A through a via electrode 42. The capacitor 20A is provided with a pair of capacitor electrodes 20Aa and 20Ab. A capacitor dielectric layer 20Ac is provided between the capacitor electrode 20Aa and the capacitor electrode 20Ab. The inductor 14 is connected to the capacitor electrode 20Aa through the via electrode 42. The capacitor electrode 20Ab is electrically connected to the filter 12M through a via electrode 44.

The above-described partial inductor 14A (see FIG. 1) is configured by the winding pattern 26a. The above-described partial inductor 14B (see FIG. 1) is configured by the winding patterns 26b to 26d and the via electrodes 28b and 28c. The partial inductor 14A and the partial inductor 14B are connected to each other by the via electrode 28a. That is, the partial inductor 14A and the partial inductor 14B are connected to each other at the connection node 14a. The via electrode 28a constitutes a part of the above-described connection node 14a (see FIG. 1). In the example shown in FIG. 3, a conductive pattern 34 is connected to one end of the winding pattern 26b, but the present invention is not limited to this feature. The portions of the winding patterns 26 other than the ends may be connected to the conductive pattern 34. In addition, the via electrodes 28 may be connected to the conductive pattern 34 at portions other than the upper portion and the lower portion thereof.

As shown in FIG. 4, the connection node 14a is electrically connected to the capacitor 20B through the conductive pattern 34, a via electrode 40, a conductive pattern 46, and a via electrode 48. The capacitor 20B is provided with a pair of capacitor electrodes 20Ba and 20Bb. The connection node 14a is electrically connected to the capacitor electrode 20Ba through the conductive pattern 34, the via electrode 40, the conductive pattern 46, and the via electrode 48. A capacitor dielectric layer 20Bc is provided between the capacitor electrode 20Ba and the capacitor electrode 20Bb. The capacitor electrode 20Bb is electrically connected to the filter 12H (see FIG. 2) via a via electrode 50.

As shown in FIG. 4, the dielectric substrate 24 includes a dielectric layer (first dielectric layer) 24A, a dielectric layer (second dielectric layer) 24B, and a dielectric layer (third dielectric layer) 24C. The dielectric layer 24B is located on the dielectric layer 24A. The relative permittivity of the dielectric layer 24B is higher than the relative permittivity of the dielectric layer 24A. The dielectric layer 24C is located on the dielectric layer 24B. The relative permittivity of the dielectric layer 24C is higher than the relative permittivity of the dielectric layer 24B.

The inductor 14 is formed in the dielectric layer 24C. Since the relative permittivity of the dielectric layer 24C is relatively low, the inductor 14 having good characteristics can be obtained.

A ground layer 52 is provided in the dielectric substrate 24. The ground layer 52 is provided at the boundary between the dielectric layer 24A and the dielectric layer 24B.

The capacitor 20A is located above the ground layer 52. The capacitor electrode 20Ab of the capacitor 20A is located in the dielectric layer 24B. The capacitor electrode 20Aa of the capacitor 20A is formed on the dielectric layer 24A. More specifically, the capacitor electrode 20Aa of the capacitor 20A is positioned at the boundary between the dielectric layer 24B and the dielectric layer 24C.

The capacitor dielectric layer 20Ac of the capacitor 20A is configured by a part of the dielectric layer 24B. The reason why the capacitor dielectric layer 20Ac is configured by a part of the dielectric layer 24B is to obtain the capacitor 20A having a sufficient capacitance. That is, since the relative permittivity of the dielectric layer 24B is relatively high, the capacitor 20A having a sufficient capacitance can be obtained.

The capacitor 20B is located above the ground layer 52. The capacitor electrode 20Bb of the capacitor 20B is located in the dielectric layer 24B. The capacitor electrode 20Ba of the capacitor 20B is formed on the dielectric layer 24B. More specifically, the capacitor electrode 20Ba of the capacitor 20B is positioned at the boundary between the dielectric layer 24B and the dielectric layer 24C.

The capacitor dielectric layer 20Bc of the capacitor 20B is configured by a part of the dielectric layer 24B. The reason why the capacitor dielectric layer 20Bc is configured by a part of the dielectric layer 24B is to obtain the capacitor 20B having a sufficient capacitance. That is, since the relative permittivity of the dielectric layer 24B is relatively high, the capacitor 20B having a sufficient capacitance can be obtained.

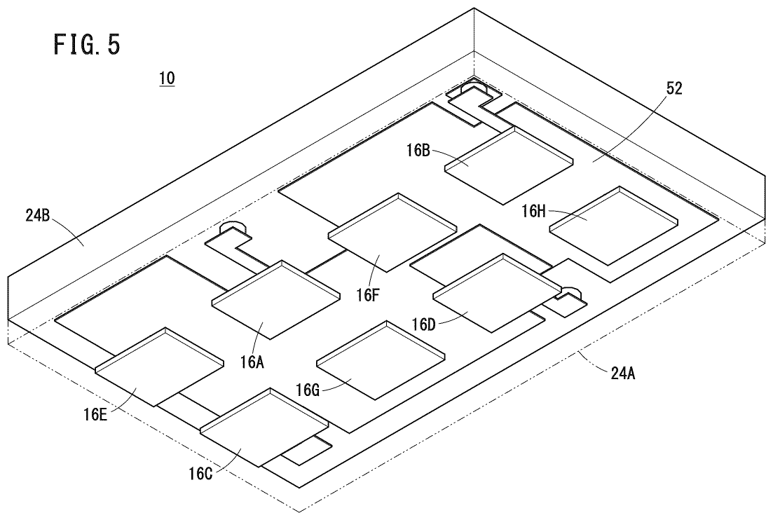

FIG. 5 is a perspective view illustrating a portion of the electronic device according to the present embodiment. FIG. 5 illustrates the electronic device 10 viewed from obliquely below.

As shown in FIG. 5, the common terminal 16A and terminals 16B to 16D are provided on the lower surface of the dielectric layer 24A (see FIG. 4). Terminals (ground electrodes) 16E to 16H are further provided on the lower surface of the dielectric layer 24A. The terminals 16E to 16H are electrically connected to the ground layer 52.

The common terminal 16A is electrically connected to the via electrode 30 as described above. The dielectric layer 24B is present between the portion of the via electrode 30 penetrating the dielectric layer 24B and the ground layer 52. The relative permittivity of the dielectric layer 24B is relatively high. Therefore, a certain amount of parasitic capacitance 22 (see FIG. 1) is generated in the common terminal 16A.

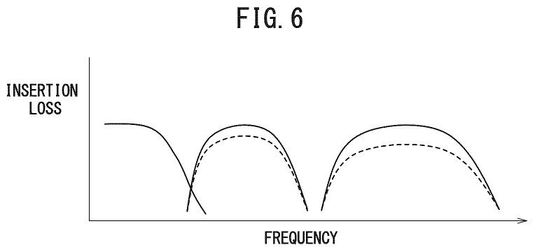

The evaluation results of the electronic device according to the present embodiment will be described with reference to FIG. 6.

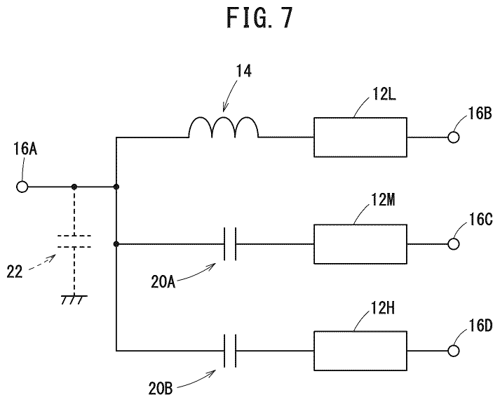

FIG. 6 is a graph illustrating an evaluation result of the electronic device according the present embodiment. The horizontal axis in FIG. 6 indicates the frequency. The vertical axis in FIG. 6 indicates the insertion loss. The solid lines in FIG. 6 indicate the characteristics of the present embodiment. The broken lines in FIG. 6 indicate the characteristics of a reference example. FIG. 7 is a circuit diagram illustrating an electronic device according to the reference example. As shown in FIG. 7, in the reference example, the filter 12M is electrically coupled to the common terminal 16A, not through the inductor 14. As shown in FIG. 7, in the reference example, the filter 12H is electrically coupled to the common terminal 16A, not through the partial inductor 14A.

As can be seen from FIG. 6, in the reference example, the insertion loss in the path including the filter 12H is relatively large. That is, in the reference example, the insertion loss in the path from the common terminal 16A to the terminal 16D is relatively large. In the reference example, the insertion loss in the path including the filter 12M is relatively large. That is, in the reference example, the insertion loss in the path from the common terminal 16A to the terminal 16C is relatively large.

In contrast, in the present embodiment, the insertion loss in the path including the filter 12H can be suppressed. That is, in the present embodiment, the insertion loss in the path from the common terminal 16A to the terminal 16D can be suppressed. In addition, in the present embodiment, insertion loss in the path including the filter 12M can be suppressed. That is, in the present embodiment, insertion loss in the path from the common terminal 16A to the terminal 16C can be suppressed.

Thus, according to the present embodiment, the filter 12H is electrically coupled to the common terminal 16A through the partial inductor 14A. Therefore, according to the present embodiment, it is possible to suppress the influence of the parasitic capacitance 22 generated in the common terminal 16A on the filter 12H. Moreover, according to the present embodiment, the filter 12H is electrically coupled to the common terminal 16A through the partial inductor 14A, but not through the partial inductor 14B. Therefore, according to the present embodiment, a moderate inductance can be obtained between the filter 12H and the common terminal 16A. Since the inductance between the filter 12H and the common terminal 16A is moderate, the characteristic of the filter 12H is not deteriorated. Moreover, according to the present embodiment, since the partial inductor 14A is a part of the inductor 14, it is not necessary to form another inductor separate from the inductor 14. According to the present embodiment, it is possible to provide an electronic device that exhibits satisfactory characteristics while satisfying the requirement of miniaturization. As described above, according to the present embodiment, it is possible to provide a more satisfactory electronic device.

### Modified Embodiment

The present invention is not necessarily limited to the above-described embodiment, and various configurations can be adopted therein without departing from the essence and gist of the present invention.

Further, in the above-described embodiment, although an exemplary case has been described in which the electronic device 10 is a demultiplexer, the present invention is not necessarily limited to this feature. The electronic device 10 may be a multiplexer. In this case, signals are input to the terminals (input terminals) 16B to 16D, and a signal is output from the common terminal (common output terminal) 16A.

The following supplementary notes are further disclosed in relation to the above-described embodiments.

### (Supplementary Note 1)

The electronic device (10) includes the dielectric substrate (24), the common terminal (16A) provided on the dielectric substrate and configured to input or output the signal, the inductor (14) formed in the dielectric substrate, the first filter (12L) formed in the dielectric substrate, and the second filter (12H) formed in the dielectric substrate, wherein the frequency of the passband of the second filter is higher than the frequency of the passband of the first filter, the first filter is electrically coupled to the common terminal through the inductor, the inductor includes the first partial inductor (14A) and the second partial inductor (14B) connected in series to the first partial inductor, and the second filter is electrically coupled to the common terminal through the first partial inductor, but not through the second partial inductor. In accordance with such a configuration, the second filter is electrically coupled to the common terminal through the first partial inductor. Therefore, in accordance with such a configuration, it is possible to suppress the influence of the parasitic capacitance generated in the common terminal on the second filter. Moreover, in accordance with such a configuration, since the second filter is electrically coupled to the common terminal, through the first partial inductor but not through the second partial inductor, a moderate inductance can be obtained between the second filter and the common terminal. Since the inductance between the second filter and the common terminal is moderate, the characteristics of the second filter are not deteriorated. Moreover, in accordance with such a configuration, since the first partial inductor is a part of the inductor, it is not necessary to form an inductor separate from the inductor. In accordance with such a configuration, it is possible to provide an electronic device that exhibits satisfactory characteristics while satisfying the requirement of miniaturization. In accordance with such a configuration, it is possible to provide a more satisfactory electronic device.

### (Supplementary Note 2)

In the electronic device according to the supplementary note 1, the dielectric substrate may include the first dielectric layer (24A), the second dielectric layer (24B) formed on the first dielectric layer and having the relative permittivity higher than the relative permittivity of the first dielectric layer, and the third dielectric layer (24C) formed on the second dielectric layer and having the relative permittivity lower than the relative permittivity of the second dielectric layer, the common terminal may be provided on a lower surface of the first dielectric layer, the inductor may be formed in the third dielectric layer, the ground layer (52) may be provided at the boundary between the first dielectric layer and the second dielectric layer, and the second filter may be electrically coupled to the common terminal, through the first capacitor (20B), the first partial inductor, and the via electrode (30) penetrating the second dielectric layer, the first capacitor including the first capacitor dielectric layer (20Bc) formed of the part of the second dielectric layer. In accordance with such a configuration, a relatively large parasitic capacitance may be generated between the via electrode and the ground layer, but since the second filter is electrically coupled to the common terminal through the first partial inductor, the influence of the parasitic capacitance on the second filter can be sufficiently suppressed.

### (Supplementary Note 3)

The electronic device according to the supplementary note 2 may further include the third filter (12M) formed in the dielectric substrate, wherein the frequency of the passband of the third filter may be higher than the frequency of the passband of the first filter and lower than the frequency of the passband of the second filter, and the third filter may be electrically coupled to the common terminal, through the second capacitor (20A), at least a part of the inductor, and the via electrode, the second capacitor including the second capacitor dielectric layer (20Ac) formed of the other part of the second dielectric layer.

Moreover, the present invention is not limited to the above-described disclosure, and various configurations can be adopted therein without departing from the essence and gist of the present invention.

### REFERENCE SIGNS LIST

10: electronic device
12H, 12L, 12M: filter
14: inductor
14A, 14B: partial inductor
14a: connection node
16A to 16H: common terminal
20A, 20B: capacitor
20Aa, 20Ab, 20Ba, 20Bb: capacitor electrode
20Ac, 20Bc: capacitor dielectric layer
22: parasitic capacitance
24: dielectric substrate
24A to 24C: dielectric layer
24a, 24b: main surface
26a, 26b, 26c, 26d: winding pattern
28a to 28c, 29, 30, 38, 40, 42, 44, 48, 50: via electrodes
32, 34, 36, 46: conductive pattern
52: ground layer
54: shield layer

1. An electronic device comprising:
a dielectric substrate;
a common terminal provided on the dielectric substrate and configured to input or output a signal;
an inductor formed in the dielectric substrate;
a first filter formed in the dielectric substrate; and
a second filter formed in the dielectric substrate,
wherein a frequency of a passband of the second filter is higher than a frequency of a passband of the first filter,
the first filter is electrically coupled to the common terminal through the inductor,
the inductor includes a first partial inductor and a second partial inductor connected in series to the first partial inductor, and
the second filter is electrically coupled to the common terminal through the first partial inductor, but not through the second partial inductor.

2. The electronic device according to claim 1, wherein the dielectric substrate includes a first dielectric layer, a second dielectric layer formed on the first dielectric layer and having a relative permittivity higher than a relative permittivity of the first dielectric layer, and a third dielectric layer formed on the second dielectric layer and having a relative permittivity lower than the relative permittivity of the second dielectric layer,
the common terminal is provided on a lower surface of the first dielectric layer,
the inductor is formed in the third dielectric layer,
a ground layer is provided at a boundary between the first dielectric layer and the second dielectric layer, and
the second filter is electrically coupled to the common terminal, through a first capacitor, the first partial inductor, and a via electrode penetrating the second dielectric layer, the first capacitor including a first capacitor dielectric layer formed of a part of the second dielectric layer.

3. The electronic device according to claim 2, further comprising a third filter formed in the dielectric substrate,
wherein a frequency of a passband of the third filter is higher than the frequency of the passband of the first filter and lower than the frequency of the passband of the second filter, and
the third filter is electrically coupled to the common terminal, through a second capacitor, at least a part of the inductor, and the via electrode, the second capacitor including a second capacitor dielectric layer formed of another part of the second dielectric layer.
